(19) United States
(12) Patent Application Publication
(10) Pub. No.: US 2005/0263807 A1
(43) Pub. Date: Dec. 1, 2005

(54) Semiconductor device and method for forming a ferroelectric capacitor of the semiconductor device

(76) Inventors: Tai-Bor Wu, Hsinchu (TW); Chun-Kai Huang, Hsinchu (TW)

Correspondence Address: LADAS & PARRY LLP, 224 SOUTH MICHIGAN AVENUE, SUITE 1600, CHICAGO, IL, 60604, US

(21) Appl. No.: 11/103,322

(22) Filed: Apr. 11, 2005

(30) Foreign Application Priority Data
Apr. 13, 2004 (TW) 093110228

(51) Int. Cl. H01L 29/76

(52) U.S. Cl. 257/295

(57) ABSTRACT

A semiconductor device includes a MOS transistor, and a ferroelectric capacitor formed on the MOS transistor and including upper and lower electrode layers and a dielectric layer sandwiched between the upper and lower electrode layers. Each of the upper and lower electrode layers is made from a Pt—PtOₓ material, in which x is an integer from 1 to 2, and the weight percentage of PtOₓ based on the total weight of the Pt—PtOₓ material is in an amount ranging from 50-100%.

### CROSS-REFERENCE TO RELATED APPLICATION

This application claims priority of Taiwanese Application No. 093110228, filed on Apr. 13, 2004.

### BACKGROUND OF THE INVENTION

1. Field of the Invention

This invention relates to a semiconductor device and a method for forming a ferroelectric capacitor of the semiconductor device, more particularly to a semiconductor device with a ferroelectric capacitor that includes electrodes of a Pt—PtOₓ material.

2. Description of the Related Art

FIG. 1 illustrates a conventional semiconductor device that includes a MOS transistor 200 and a ferroelectric capacitor 1 formed on the MOS transistor 200 through semiconductor processing techniques. The ferroelectric capacitor 1 is electrically connected to the MOS transitor 200 through a conductive wire 300. The ferroelectric capacitor 1 includes upper and lower electrode layers 13, 11 and a dielectric layer 12 sandwiched between the upper and lower electrode layers 13, 11. The dielectric layer 12 is made from a ferroelectric material, such as PbZr₁₋ₓTiₓO₃ (PZT), Ba₁₋ₓSrₓTiO₃ (BST), and Ba(Zn₁₋ₓTaₓ)O₃ (BZT). The upper and lower electrode layers 13, 11 are made from a noble metal, such as platinum (Pt), or a metal compound, such as RuO₂, IrO₂, and LaNiO₃.

Since IrO₂ and LaNiO₃ are difficult to be etched, and since RuO₂ can produce toxic gas during etching when using chlorine- or fluorine-containing etchant, Pt is usually used as a material for the upper and lower electrode layers 13, 11. However, etching of a Pt electrode is still difficult, and fine pattern of the Pt electrode is very difficult to obtain using current etching techniques. In addition, hydrogen degradation of the dielectric layer 12 induced in the hydrogen-gas annealing of the conductive wire 300 occurs due to catalytic characteristics of the Pt electrode (i.e., the upper and lower electrodes 13, 11), which results in formation of hydrogen ions that penetrate through the Pt electrode and into the dielectric layer 12.

### SUMMARY OF THE INVENTION

The object of the present invention is to provide a semiconductor device with a ferroelectric capacitor that is capable of overcoming the aforesaid drawback of the prior art.

Another object of this invention is to provide a method for forming the ferroelectric capacitor on a MOS transistor of the semiconductor device.

According to one aspect of this invention, there is provided a semiconductor device that comprises: a MOS transistor; and a ferroelectric capacitor formed on the MOS transistor and including upper and lower electrode layers and a dielectric layer sandwiched between the upper and lower electrode layers. Each of the upper and lower electrode layers is made from a Pt—PtOₓ material, in which x is an integer from 1 to 2, and the weight percentage of PtOₓ based on the total weight of the Pt—PtOₓ material is in an amount ranging from 50-100%.

According to another aspect of this invention, there is provided a method for forming a ferroelectric capacitor on a MOS transistor of a semiconductor device. The method comprises the steps of; forming a lower electrode layer on a reference surface; forming a dielectric layer on the lower electrode layer; and forming an upper electrode layer on the dielectric layer. Each of the upper and lower electrode layers is made from a Pt—PtOₓ material, in which x is an integer from 1 to 2, and the weight percentage of PtOₓ based on the total weight of the Pt—PtOₓ material is in an amount ranging from 50-100%.

### BRIEF DESCRIPTION OF THE DRAWINGS

Other features and advantages of the present invention will become apparent in the following detailed description of the preferred embodiment of the invention, with reference to the accompanying drawings, in which:

FIG. 1 is a schematic view to illustrate a ferroelectric capacitor of a conventional semiconductor device;

FIG. 2 is a schematic view of the preferred embodiment of a semiconductor device according to this invention, with an unpatterned ferroelectic capacitor;

FIG. 3 is a schematic view to illustrate the patterned ferroelectric capacitor of the semiconductor device of the preferred embodiment;

FIG. 4 is a graph of etching rate and selectivity for the semiconductor device of the preferred embodiment and the conventional semiconductor device;

FIG. 5 is a graph of XPS intensity for the semiconductor device of the preferred embodiment and the conventional semiconductor device; and

FIG. 6 is a graph of polarization versus electric field (P-E hysteresis curves) for the semiconductor device of the preferred embodiment and the conventional semiconductor device.

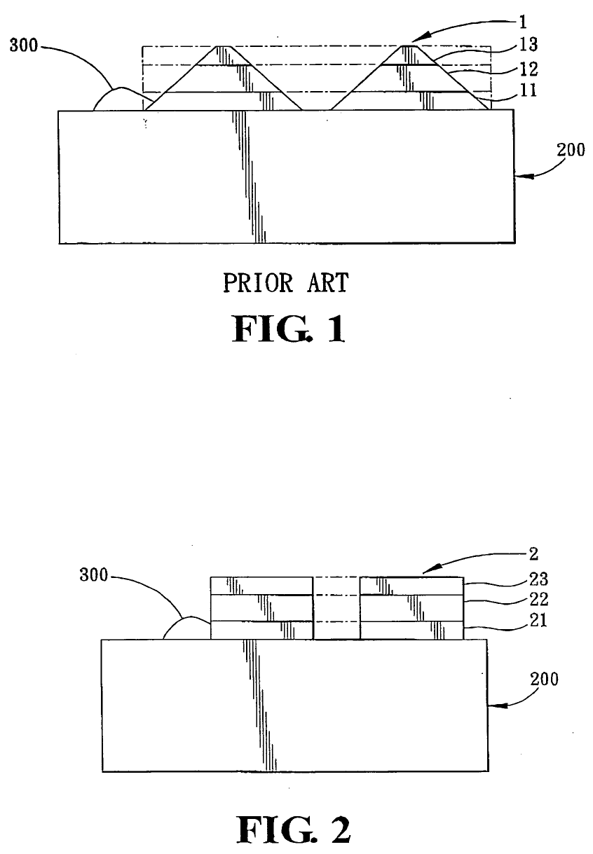

### DETAILED DESCRIPTION OF THE PREFERRED EMBODIMENT

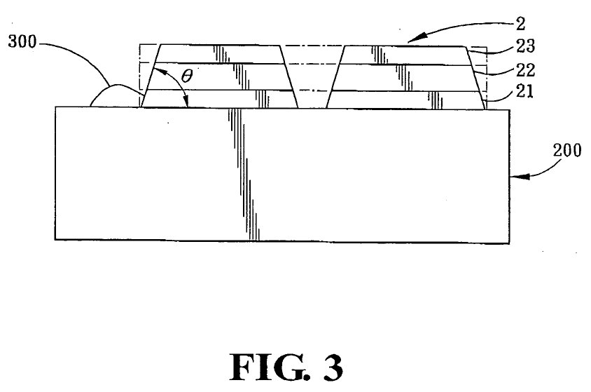

FIG. 2 illustrates the preferred embodiment of an unpatterned ferroelectric capacitor of a semiconductor device according to the present invention. FIG. 3 illustrates the patterned ferroelectric capacitor of the semiconductor device.

The semiconductor device includes: a MOS transistor 200; a ferroelectric capacitor 2 formed on the MOS transistor 200 and including upper and lower electrode layers 23, 21 and a dielectric layer 22 sandwiched between the upper and lower electrode layers 23, 21; and a conductive wire 300 electrically connected to the ferroelectric capacitor 2 and the MOS transistor 200. Each of the upper and lower electrode layers 23, 21 is made from a Pt—PtOₓ material, in which x is an integer from 1 to 2, and the weight percentage of PtOₓ based on the total weight of the Pt—PtOₓ material is in an amount ranging from 50-100%.

In this embodiment, the ferroelectric capacitor 2 has a pattern of two truncated conical bodies (see FIG. 3), each of which includes the upper and lower electrode layers 23, 21 and the dielectric layer 22.

The dielectric layer 22 is made from a ferroelectric material selected from the group consisting of PbZr₁₋ₓTiₓO₃ (PZT), Strontium bismuth tantalite (SBT), Ba(Zn₁₋ₓTaₓ)O₃ (BZT) Ba₁₋ₓSrₓTiO₃ (BST), and combinations thereof.

The ferroelectric capacitor 2 is formed on a reference surface of the MOS transistor 200 according to a method of this invention. The method includes the steps of: forming the lower electrode layer 21 on the reference surface using deposition techniques, such as physical vapor deposition (PVD), sputtering, chemical vapor deposition (CVD), or Sol-Gel techniques; forming the dielectric layer 22 on the lower electrode layer 21 using the aforesaid deposition techniques or the Sol-Gel techniques; and forming the upper electrode layer 23 on the dielectric layer 22 using the aforesaid deposition techniques or the Sol-Gel techniques.

In this embodiment, formation of the upper and lower electrode layers 23, 21 is performed using sputtering techniques by sputtering a Pt target in a gas mixture of Ar/O₂ such that formation of PtOₓ through reaction of Pt with the oxygen of the gas mixture occurs during deposition of Pt on the reference surface. Preferably, the ratio of Ar to O₂ of the gas mixture ranges from 50:50 to 60:40. The sputtering is conducted at a temperature ranging from 140 to 180° C.

Patterning of the ferroelectric capacitor 2 is conducted by dry etching techniques, such as plasma etching, so as to form the two truncated conical bodies shown in FIG. 3. An etch slope, represented by an angle θ shown in FIG. 3, over 75 degrees can be obtained for the truncated conical bodies, due to reduction in the sidewall redeposition during etching. The result is an improvement over the conventional semiconductor device with Pt electrodes having sidewall slopes less than 45 degrees.

After formation of the conductive wire 300, the same is subjected to hydrogen-gas annealing in a gas mixture of N₂/H₂ at a temperature ranging from 280 to 360° C. for reducing the resistance of the conductive wire 300. Preferably, the concentration of the hydrogen present in the gas mixture is 2 to 5%.

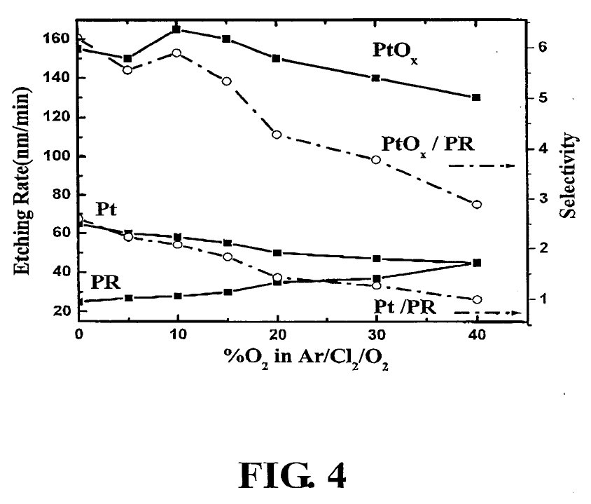

FIG. 4 shows etching rate for a PtOₓ-containing film and a Pt film, as well as their etching selectivity against a phtoresist (PR) film, as a function of O₂ content in a Ar/Cl₂/O₂ plasma. The etching test was conducted at a gas pressure of 5 mTorr, a source power of 2100 W, and a bias power of 250 W. The results show that the PtOₓ-containing film has a much higher etching rate and etching selectivity than those of Pt film.

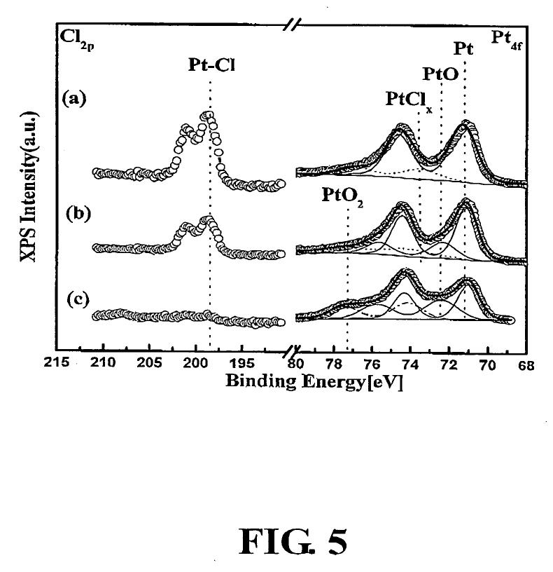

FIG. 5 shows intensity of x-ray photoelectron spectroscopy (XPS) of Cl₂ₚ and Pt_{4f} electrons of the etched PtOₓ-containing film and the PT film. In FIG. 5, (a) represents XPS of Pt film in Ar/Cl₂ (20) plasma, (b) represents XPS of PtOₓ-containing film in Ar/Cl₂(20%) plasma, and (c) represents XPS of PtOₓ-containing film in Ar/Cl₂(20%)/O₂(50%) plasma. The results show that less PtClₓ redeposited on the PtOₓ-containing film than on the Pt film for etching in the Ar/Cl₂ plasma, and that the redeposition of PtClₓ can be well eliminated by addition of O₂ in the plasma. It is noted that an additional peak corresponding to the PtO₂ phase appears at the binding energy of 77.3 eV for PtOₓ-containing film etching in the Ar/Cl₂(20%)/O₂(50%) plasma The result indicates that the PtOₓ-containing film can be further oxidized by oxygen plasma to form a PtO₂ layer on the etched surface, which, was not observed in the etching of Pt film with oxygen plasma.

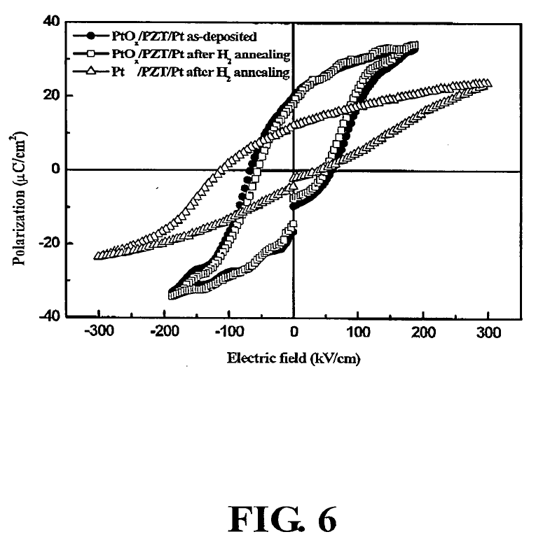

FIG. 6 shows the polarization versus electric field (P-E) hysteresis curves for capacitors with different electrodes (i.e., Pt electrode and PtOₓ electrode). The capacitors include electrodes coated on a PZT film, which were annealed in a H₂ plasma at 300° C. for one minute. The results show that the P-E characteristics of the PtOₓ electrode formed capacitor remains unchanged before and after hydrogen plasma annealing, whereas the Pt electrode formed capacitor degrades significantly. The high degradation resistance reveals the hydrogen blocking ability of the PtOₓ electrode, thereby eliminating the hydrogen degradation of the dielectric layer as encountered in the conventional semiconductor device during hydrogen gas annealing of the conductive wire of the semiconductor device.

With the inclusion of PtOₓ in the material for forming the upper and lower electrodes 23, 21 of the ferroelectric capacitor 2 of the semiconductor device of this invention, the aforesaid drawbacks associated with the prior art can be eliminated.

While the present invention has been described in connection with what is considered the most practical and preferred embodiments, it is understood that this invention is not limited to the disclosed embodiments but is intended to cover various arrangements included within the spirit and scope of the broadest interpretations and equivalent arrangements.

1. A semiconductor device comprising:
a MOS transistor; and
a ferroelectric capacitor formed on said MOS transistor and including upper and lower electrode layers and a dielectric layer sandwiched between said upper and lower electrode layers;
wherein each of said upper and lower electrode layers is made from a Pt—PtOₓ material, in which x is an integer from 1 to 2, and the weight percentage of PtOₓ based on the total weight of the Pt—PtOₓ material is in an amount ranging from 50-100%.

2. The semiconductor device of claim 1, wherein said dielectric layer is made from a ferroelectric material selected from the group consisting of PZT, SET, BZT, BST, and combinations thereof.

3. A method for forming a ferroelectric capacitor on a MOS transistor of a semiconductor device, comprising:
forming a lower electrode layer on a reference surface;
forming a dielectric layer on the lower electrode layer; and
forming an upper electrode layer on the dielectric layer;
wherein each of the upper and lower electrode layers is made from a Pt—PtOₓ material, in which x is an integer from 1 to 2, and the weight percentage of PtOₓ based on the total weight of the Pt—PtOₓ material is in an amount ranging from 50-100%.

4. The method of claim 3, wherein each of the upper and lower electrode layers is formed by sputtering a Pt target in a gas mixture of Ar/O₂ such that formation of PtOₓ through reaction of Pt with the oxygen of the gas mixture occurs during deposition of Pt on the reference surface.

5. The method of claim 4, wherein the ratio of Ar to O₂ of the gas mixture ranges from 50:50 to 60:40.

6. The method of claim 4, wherein the sputtering deposition is conducted at a temperature ranging from 140 to 180° C.
